(19) United States
(12) Patent Application Publication
(10) Pub. No.: US 2011/0176379 A1
(43) Pub. Date: Jul. 21, 2011

(54) SEMICONDUCTOR MEMORY DEVICE HAVING MEMORY CELL ARRAY OF OPEN BIT LINE TYPE AND CONTROL METHOD THEREOF

(76) Inventors: Shinichi TAKAYAMA, Tokyo (JP); Akira Kotabe, Tokyo (JP); Kazuo Ono, Tokyo (JP); Tomonori Sekiguchi, Tokyo (JP); Yoshimitsu Yanagawa, Tokyo (JP); Riichiro Takemura, Tokyo (JP)

(21) Appl. No.: 13/008,408

(22) Filed: Jan. 18, 2011

(30) Foreign Application Priority Data
Jan. 18, 2010 (JP) 2010-008269

(51) Int. Cl. G11C 7/06

(52) U.S. Cl. 365/208

(57) ABSTRACT

A semiconductor memory device includes: first and second bit lines of an open bit-line system; a sense amplifier that amplifies a potential difference between the first and second bit lines; a pair of first and second local data lines corresponding to the first and second bit lines, respectively; and a write amplifier circuit. The write amplifier circuit changes a potential of the second local data line without changing a potential of the first local data line at a time of writing data for the first bit line, and changes a potential of the first local data line without changing a potential of the second local data line at a time of writing data for the second bit line.

### BACKGROUND OF THE INVENTION

1. Field of the Invention

The present invention relates to a semiconductor memory device and a control method thereof, and more particularly relates to a semiconductor memory device having an open-bit-line memory cell array and a control method of the semiconductor memory device.

2. Description of Related Art

Many of semiconductor memory devices represented by a DRAM (Dynamic Random Access Memory) read data by amplifying a potential difference appearing between a pair of bit lines. When data is written into such a semiconductor memory device, generally, write data is supplied to one of the bit lines and an inversion signal of the write data is supplied to the other bit line that becomes a reference side.

For example, Japanese Patent Application Laid-open No. H6-131867 discloses, as shown in FIG. 5 of the patent application, performing a write operation by outputting complimentary data to a pair of global data lines (GDm and /GDm) and to a pair of data lines (Dmm and /Dmm) provided between the pair of global data lines and a memory cell.

In this manner, according to such a conventional semiconductor memory device, it is a common procedure to simultaneously supply complimentary data to a pair of bit lines at a write operation.

However, when a pair of bit lines is driven by complementary data in an open-bit-line semiconductor memory device, there is a possibility that data in a memory cell other than a memory cell into which data is to be written is damaged by noise between bit lines. In this context, the open bit-line system is a system in which a pair of bit lines is wired in mutually 180° different directions as viewed from a sense amplifier (see Japanese Patent Application Laid-open Nos. 2000-222876 and 2009-266300). In the open bit-line system, a pair of bit lines allocated to the same amplifier are not adjacent to each other, unlike in a folded bit-line system. Adjacent bit lines are all allocated to other sense amplifiers.

Therefore, at overwriting data in a memory cell connected to a predetermined bit line, there is a problem that, due to noise between bit lines, potentials of bit lines which are adjacent to the bit line into which data is written fluctuate. In a write operation, bit lines into which data is not written are used to read and restore data in a memory cell. Therefore, when potentials fluctuate due to noise, restored data may be erroneously inverted.

### SUMMARY

In one embodiment, there is provided a semiconductor memory device that includes: a plurality of memory cells each of which includes a cell transistor, first and second bit lines connected to corresponding memory cells, respectively, a sense amplifier that is provided while being sandwiched between the first and second bit lines, and amplifies a voltage between the first and second bit lines, first and second data lines corresponding to the first and second bit lines, respectively, and a write amplifier that supplies a potential corresponding to write data to the first and second data lines. The write amplifier changes a potential of the second data line without changing a potential of the first data line at a time of writing the write data into the memory cell by selecting the cell transistor corresponding to the first bit line, and changes a potential of the first data line without changing a potential of the second data line at a time of writing the write data into the memory cell by selecting the cell transistor corresponding to the second bit line.

In another embodiment, there is provided a semiconductor memory device that includes: first and second sub-array regions, first and second bit lines provided in the first and second sub-array regions, respectively, a first sense amplifier region provided between the first and second sub-array regions, a first sense amplifier that is provided in the first sense amplifier region and amplifies a potential difference between the first and second bit lines, and a write amplifier that drives the first and second bit lines based on write data. The write amplifier drives at least the second bit line such that a potential change amount of the second bit line becomes larger than a potential change amount of the first bit line at a time of overwriting the write data into a memory cell connected to the first bit line, and drives at least the first bit line such that a potential change amount of the first bit line becomes larger than a potential change amount of the second bit line at a time of overwriting the write data into a memory cell connected to the second bit line.

In another embodiment, there is provided a control method of a semiconductor memory device having an open-bit-line memory cell array. The method includes steps of: equalizing first and second bit lines connected to a same sense amplifier at a precharge level, driving the second bit line while holding the first bit line at the pre-charge level in response to a request for a write operation to a memory cell connected to the first bit line, and driving the first bit line while holding the second bit line at the pre-charge level in response to a request for a write operation to a memory cell connected to the second bit line.

According to the present invention, because noise from a bit line connected to a memory cell into which data is written is substantially reduced, data in a memory cell restored during a write operation other than a memory cell in which data is written is protected.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram of an overall configuration of a semiconductor memory device according to an embodiment of the present invention;

FIG. 2 is an enlarged diagram of a part of the memory cell array;

FIG. 3 is a circuit diagram of the sub-array region in more detail;

FIG. 4 is a schematic diagram for explaining a relationship between a row address and a selected sub-array region;

FIG. 5 is a schematic block diagram for explaining a wiring and a signal concerning a write operation;

FIG. 6 is a circuit diagram of the write amplifier circuit;

FIG. 7 is a circuit diagram of the cross area and the sense amplifier;

FIG. 8 is a waveform diagram for explaining a write operation of the semiconductor memory device according to the present embodiment;

FIG. 9 is another waveform diagram for explaining a write operation of the semiconductor memory device according to the present embodiment;

FIG. 10 is another waveform diagram for explaining a write operation of the semiconductor memory device according to the present embodiment; and

FIG. 11 is a block diagram showing an overall configuration of a semiconductor memory device according to a modification.

### DETAILED DESCRIPTION OF THE EMBODIMENTS

A representative example of a technical concept for solving the problem of the present invention is described below. It is needless to mention that the contents that the present application is to claim for patent are not limited to the following technical concept, but to the description of the appended claims. That is, the present invention has a technical concept of performing a control, in a write operation of a semiconductor memory device employing a so-called open bit-line system, that a potential change amount in a data line (for example, MIOB) corresponding to the other bit line (for example BLB) becomes larger than a potential change amount in a data line (for example, MIOT) corresponding to a bit line (for example, BLT) in which a memory cell selected by a word line is present. With this arrangement, noise from the bit line connected to a memory cell into which data is written is substantially reduced during a period until when a restore operation is started in memory cells other than a memory cell in which data is written. As a result, it is possible to prevent damaging of data in memory cells restored during a write operation other than the memory cell in which data is written.

Preferred embodiments of the present invention will be explained below in detail with reference to the accompanying drawings.

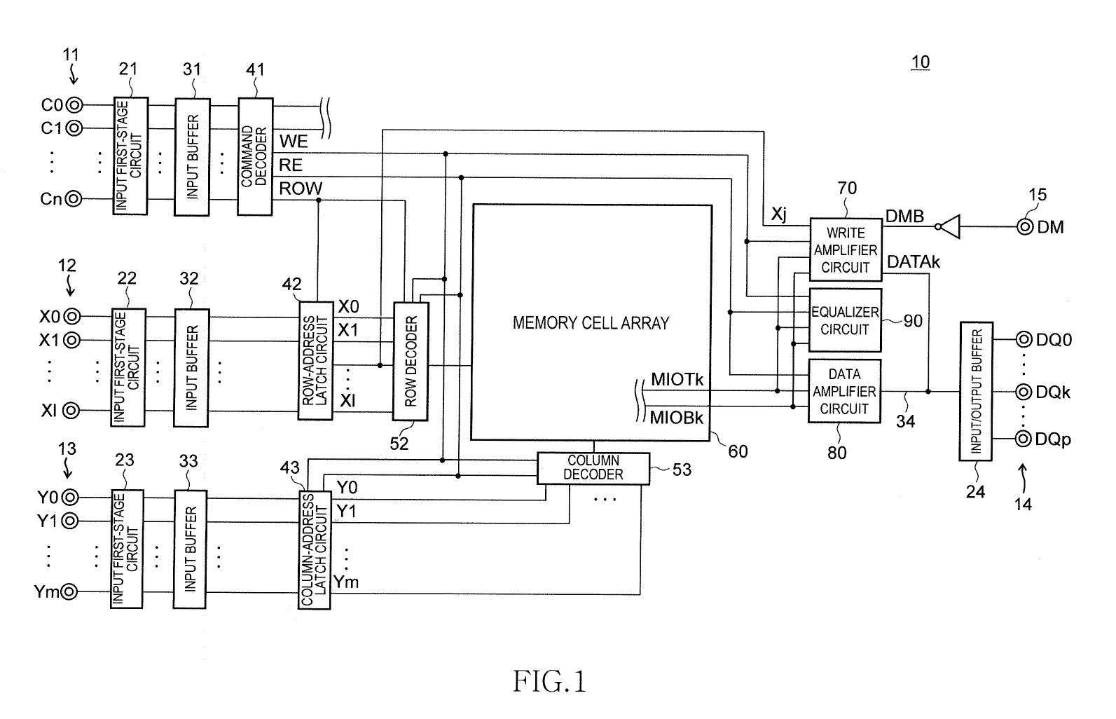

FIG. 1 is a block diagram of an overall configuration of a semiconductor memory device according to an embodiment of the present invention.

As shown in FIG. 1, a semiconductor memory device 10 according to the present embodiment includes at least a command input terminal 11, a row-address input terminal 12, a column-address input terminal 13, a data input/output terminal 14, and a data mask terminal 15, as external terminals. Although not shown in FIG. 1, the semiconductor memory device also includes a power source terminal, a clock input terminal or the like.

The command input terminal 11 is input with command signals C0 to Cn. The command signals C0 to Cn are supplied to a command decoder 41 via an input first-stage circuit 21 and an input buffer 31. The command decoder 41 activates various internal commands based on a combination of the command signals C0 to Cn. Internal commands generated by the command decoder 41 include a write enable signal WE, a read enable signal RE, and a row activation signal ROW, as shown in FIG. 1. The semiconductor memory device 10 according to the present embodiment is simultaneously input with a row address signal and a column address signal, unlike an ordinary DRAM using an address multiplex system. Therefore, regarding the command signals C0 to Cn input to the command input terminal 11, a row-system command and a column-system command are not sequentially input but are simultaneously input.

The row-address input terminal 12 is supplied with row address signals X0 and X1. The row address signals X0 and X1 are supplied to a row-address latch circuit 42 via an input first-stage circuit 22 and an input buffer 32. The row-address latch circuit 42 latches the row address signals X0 and X1 in response to the row activation signal ROW, and supplies the latched signals to a row decoder 52. The row decoder 52 decodes the row address signals X0 and X1, and supplies the decoded signals to a memory cell array 60. Accordingly, a row system is selected in the memory cell array 60. An operation of the row decoder 52 is controlled by the row activation signal ROW, the write enable signal WE, and the read enable signal RE. Out of the row addresses X0 and X1 output from the row-address latch circuit 42, a predetermined bit Xj is also supplied to a write amplifier circuit 70. The significance of supplying the address signal Xj to the write amplifier circuit 70 is explained in detail later.

The column-address input terminal 13 is supplied with column address signals Y0 to Ym. The column address signals Y0 to Ym are supplied to a column-address latch circuit 43 via an input first-stage circuit 23 and an input buffer 33. The column-address latch circuit 43 latches the column address signals Y0 to Ym in response to the write enable signal WE and the read enable signal RE, and supplies these signals to a column decoder 53. The column decoder 53 decodes the column address signals Y0 to Ym, and supplies the decoded signals to the memory cell array 60. Accordingly, a column system is selected in the memory cell array 60. An operation of the column decoder 53 is also controlled by the write enable signal WE and the read enable signal RE.

The data input/output terminal 14 is connected to an input/output buffer 24, and outputs read data DQ0 to DQp and inputs write data DQ0 to DQp. As shown in FIG. 1, the input/output buffer 24 is connected to the write amplifier circuit 70 and a data amplifier circuit 80 via a data bus 34. The data bus 34 is provided by the same number as that of terminals of the data input/output terminal 14 (=p+1). For the sake of simplicity, FIG. 1 shows only one data bus 34 that transmits data DATAk corresponding to data DQk.

The write amplifier circuit 70 is activated based on the write enable signal WE, and drives a pair of main data lines MIOT and MIOB based on write data supplied via the data bus 34. Each of the pair of main data lines MIOT and MIOB is a complimentary data line that connects the memory cell array 60, the write amplifier circuit 70, and the data amplifier circuit 80. For the sake of simplicity, FIG. 1 shows only a pair of main data lines MIOTk and MIOBk corresponding to the data DQk (DATAk). The write amplifier circuit 70 is supplied with the address signal Xj as described above, and is also supplied with an inversion signal DMB of a data mask signal DM via the data mask terminal 15. An operation of the write amplifier circuit 70 is controlled based on a logic level of the address signal Xj and the presence of activation of the data mask signal DMB. Details of the operation are described later.

The data amplifier circuit 80 is activated based on the read enable signal RE, and drives the data bus 34 based on data read from the memory cell array 60 via the pair of main data lines MIOT and MIOB.

Further, the pair of main data lines MIOT and MIOB is also connected to an equalizer circuit 90. The equalizer circuit 90 operates based on the write enable signal WE and the read enable signal RE, and precharges the pair of main data lines MIOT and MIOB at the same potential.

The overall configuration of the semiconductor memory device 10 according to the present embodiment is as described above.

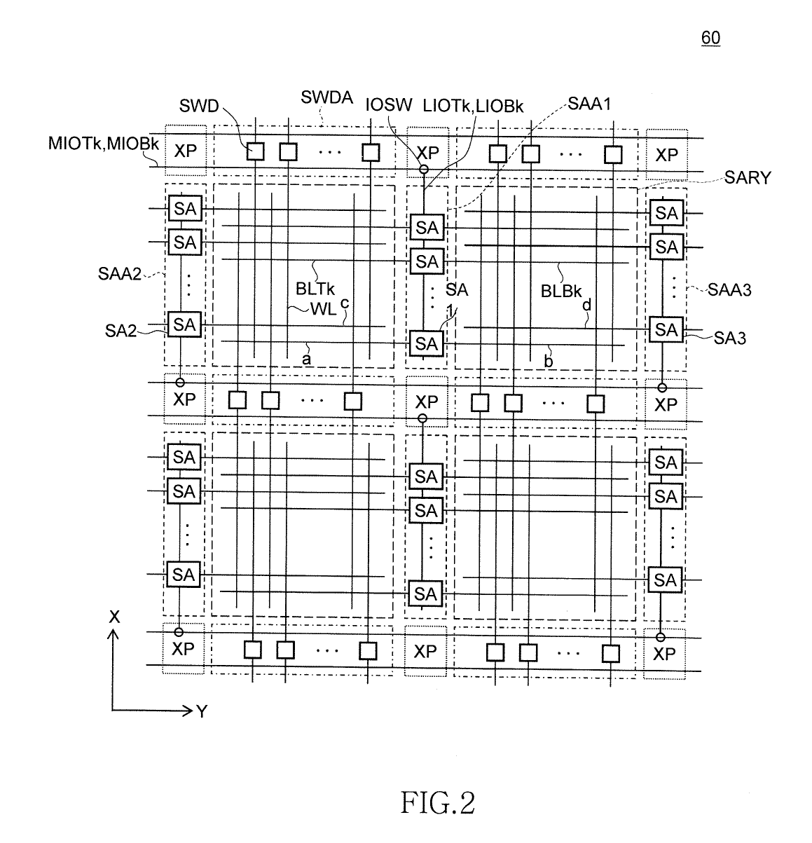

FIG. 2 is an enlarged diagram of a part of the memory cell array 60.

As shown in FIG. 2, sub-array regions SARY are arranged in a matrix shape in an X direction (a row direction) and a Y direction (a column direction) at the inside of the memory cell array 60. Sub-word driver arrays SWDA are arranged at both sides of each of the sub-array regions SARY in the X direction, and sense amplifier arrays SAA are arranged at both sides of each of the sub-array regions SARY in the Y direction.

The sub-word driver arrays SWDA are regions in which plural sub-word drivers SWD are arranged in the Y direction. The sub-word drivers SWD drive corresponding sub-word lines WL, and an operation of the sub-word drivers SWD is controlled by an output signal of the row decoder 52 shown in FIG. 1. As shown in FIG. 2, the sub-word lines WL extend to the X direction in the sub-array regions SARY. In an example shown in FIG. 2, the sub-word lines WL provided in two sub-array regions SARY respectively adjacent in the X direction are simultaneously driven by one sub-word driver SWD. Based on this configuration, a layout pitch of the sub-word drivers SWD in the Y direction is enlarged to two times.

The sense amplifier arrays SAA are regions in which plural sense amplifiers SA are arranged in the X direction. The sense amplifiers SA respectively amplify a potential difference of a corresponding pair of bit lines BLT and BLB. The bit lines BLT and BLB extend to the Y direction in each of the sub-array regions SARY. Bit lines BLTk and BLBk shown in FIG. 2 are allocated to the data DQk. As shown in FIG. 2, the bit lines BLTk and BLBk allocated to the same sense amplifier SA are provided in two sub-array regions SARY adjacent in the Y direction. That is, the memory cell array 60 has the so-called open bit-line system. As shown in FIG. 2, bit lines adjacent in the X direction in the sub-array regions SARY are allocated to the sense amplifiers SA included in mutually different sense amplifier arrays SAA. That is, bit lines are alternately connected to left and right sense amplifier arrays SAA shown in FIG. 2.

As shown in FIG. 2, a pair of local data lines LIOT and LIOB is wired in each of the sense amplifier arrays SAA. The pair of local data lines LIOT and LIOB connects the sense amplifier SA and the pair of main data lines MIOT and MIOB. A pair of local data lines LIOTk and LIOBk shown in FIG. 2 corresponds to the data DQk. For the sake of simplicity, each pair of local data lines LIOT and LIOB are shown by one solid line in FIG. 2. In practice, these lines are configured by a pair of wirings. This similarly applies to the pair of main data lines MIOT and MIOB. Although each pair of main data lines MIOT and MIOB is shown by one solid line in FIG. 2, these lines are configured by a pair of wirings in practice. That is, the pair of main data lines MIOT and MIOB and the pair of local data lines LIOT and LIOB are complementary wirings that transmit signals of differential formats. On the other hand, the data buses 34 shown in FIG. 1 are wirings that transmit signals of a single end format.

Among the sense amplifiers SA included in the sense amplifier arrays SAA, which one of the sense amplifiers SA is to be connected to the pair of local data lines LIOT and LIOB is controlled by an output signal of the column decoder 53 shown in FIG. 1.

As shown in FIG. 2, data switch circuits IOSW are arranged in cross areas XP as intersections between the sense amplifier arrays SAA extended to the X direction and the sub-word driver arrays SWDA extended to the Y direction. The data switch circuits IOSW connect the pair of main data lines MIOT and MIOB and the pair of local data lines LIOT and LIOB.

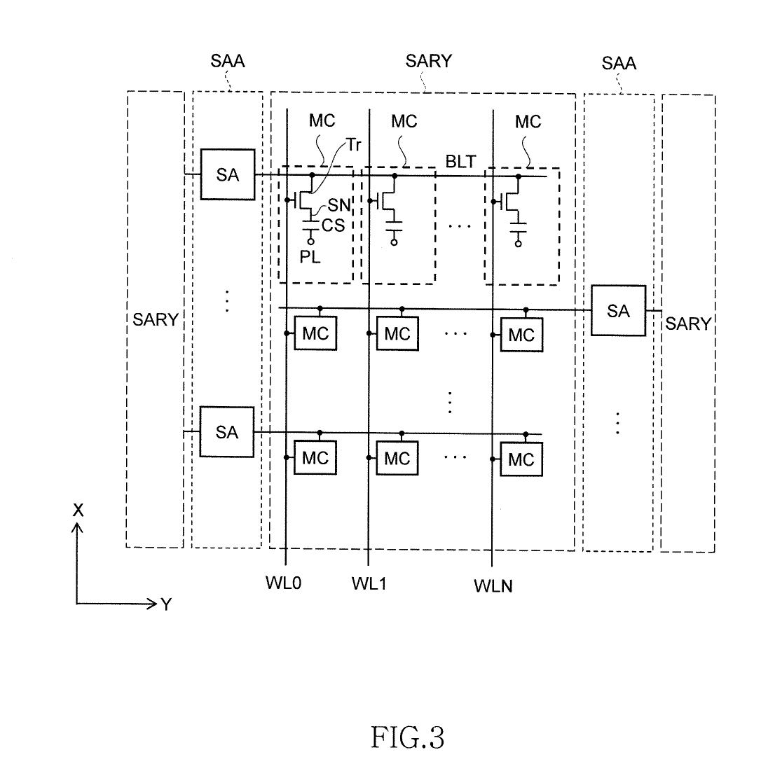

FIG. 3 is a circuit diagram of the sub-array region SARY in more detail.

As shown in FIG. 3, memory cells MC are arranged at intersections between the sub-word lines WL and the bit lines BLT and BLB, in each of the sub-array regions SARY. Each of the memory cells MC is a so-called DRAM cell, and is configured by one MOS transistor (cell transistor) Tr and one cell capacitor Cs. One of a source and a drain of the cell transistor Tr is connected to a corresponding bit line BLT or BLB. The other one of the source and the drain is connected to a storage node SN, and a gate electrode is connected to a corresponding sub-word line WL. One of terminals of the cell capacitor Cs is connected to the storage node SN, and the other terminal is connected to a common plate PL. A plate potential VPLT is given to the common plate PL. When the open bit-line system is used as is used in the present embodiment, the memory cells MC can be arranged at all intersections between word lines and bit lines. Therefore, there is an advantage that an occupied area per one memory cell MC can be reduced.

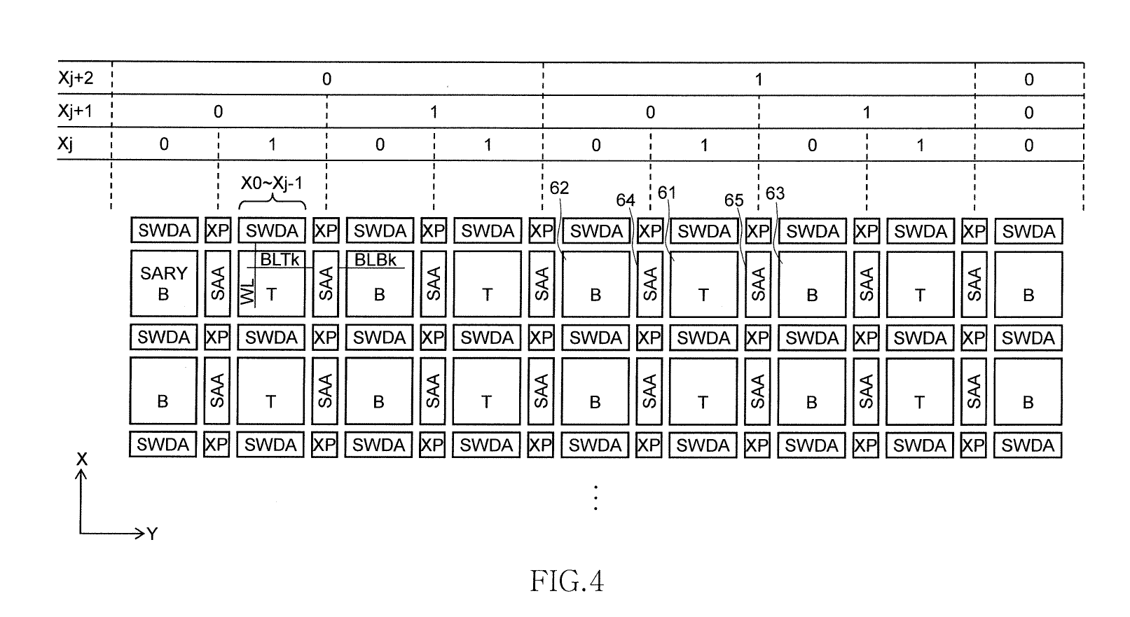

FIG. 4 is a schematic diagram for explaining a relationship between a row address and a selected sub-array region SARY.

As shown in FIG. 4, the sub-array region SARY in the Y direction is selected by row addresses Xj+2, Xj+1, and Xj. Specifically, nine sub-array regions SARY are provided in the Y direction in the memory cell array 60. One or two of the nine sub-array regions SARY arranged at ends are selected by the row addresses Xj+2, Xj+1, and Xj. The two sub-array regions SARY arranged at ends have a half number of bit lines unlike other sub-array regions SARY. Therefore, these two sub-array regions SARY are selected simultaneously. As shown in FIG. 4, among the row addresses Xj+2, Xj+1, and Xj used to select the sub-array regions SARY, Xj is used as a lowest-order bit. When a logic level of Xj is “1”, the sub-array region SARY denoted as “T” in FIG. 4 is selected. When this logic level is “0”, the sub-array region SARY denoted as “B” in FIG. 4 is selected.

To “select” the sub-array region SARY means to activate a corresponding one of the sub-word driver SWD. Because the memory cell array 60 has the open bit-line structure in the present embodiment, when a certain sub-array region SARY is selected, a half of bit lines provided in the sub-array regions SARY adjacent in the Y direction are used as reference-side bit lines. For example, when a sub-array region 61 shown in FIG. 4 is selected among bit lines included in the sub-array region 61 regarding a bit line connected to a left-side sense amplifier array 64, a bit line in a sub-array region 62 adjacent at the left side becomes a reference side. Regarding a bit line connected to a right-side sense amplifier array 65, a bit line in a sub-array region 63 adjacent at the right side becomes a reference side.

Accordingly, when the address signal Xj is at a high level, the sub-array region SARY denoted as “T” in FIG. 4 becomes a selection side, and the sub-array region SARY denoted as “B” in FIG. 4 becomes a reference side. When the address signal Xj is at a low level, the sub-array region SARY denoted as “B” in FIG. 4 becomes a selection side, and the sub-array region SARY denoted as “T” in FIG. 4 becomes a reference side. This address signal Xj is supplied to the write amplifier circuit 70, and the write amplifier circuit 70 drives one of the pair of main data lines MIOT and MIOB based on a logic level of the address signal Xj.

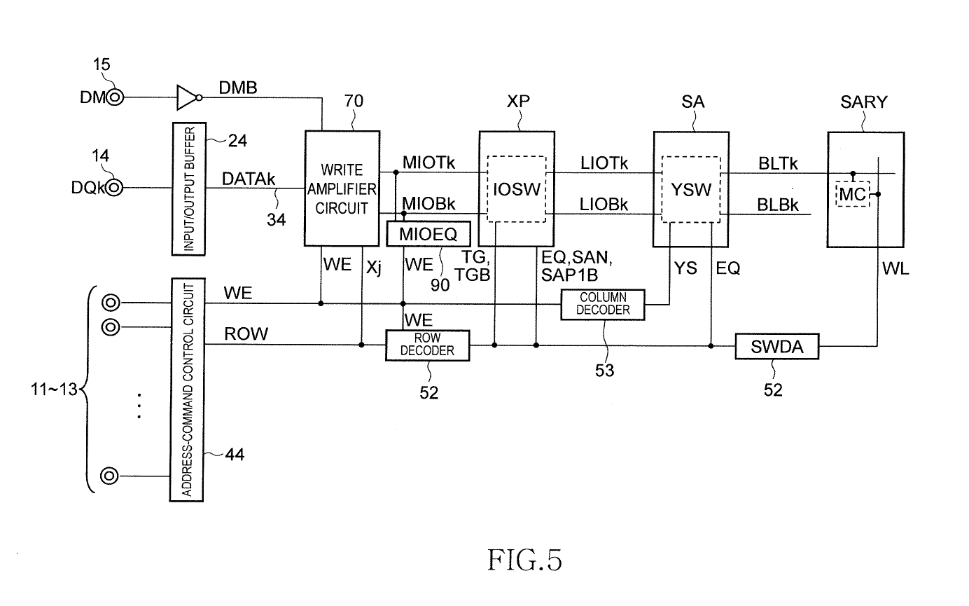

FIG. 5 is a schematic block diagram for explaining a wiring and a signal concerning a write operation.

As shown in FIG. 5, the write data DQk input from the data input/output terminal 14 is supplied to the write amplifier circuit 70 via the input/output buffer 24 and the data bus 34. The write amplifier circuit 70 increases or decreases the potential of one of the pair of main data lines MIOTk and MIOBk precharged at the same potential by the equalizer circuit 90. Which one of the pair of main data lines MIOTk and MIOBk is to be driven is determined by a logic level of the address Xj. Whether the potential of the main data line MIOTk or MIOBk is to be increased or decreased is determined by a logic level of DATAk supplied to the data bus 34. Operation timings of the write amplifier circuit 70 and the equalizer circuit 90 are controlled by the write enable signal WE. An address-command control circuit 44 shown in FIG. 5 is a circuit block including the input first-stage circuits 21 to 23, the input buffers 31 to 33, the command decoder 41, the row-address latch circuit 42, and the column-address latch circuit 43 shown in FIG. 1.

FIG. 5 is an example that the memory cell MC into which data is to be written is connected to the bit line BLTk. In this case, among the pair of main data lines MIOTk and MIOBk, the main data line MIOBk is driven by the write amplifier circuit 70. Therefore, the main data line MIOTk is not driven, and is maintained at a precharge level.

A potential change of the main data line MIOTk or MIOBk is reflected to the local data line LIOTk or LIOBk via the data switch circuit IOSW provided in the cross area XP. The data switch circuit IOSW is controlled by transfer signals TG and TGB generated by a row address or a command signal. The cross area XP includes an equalizer circuit and a sense activation circuit described later. Signals EQ, SAN, and SAP1B that control these circuits are also supplied to the cross area XP. The signals EQ, SAN, and SAP1B are also generated by the row address and the command signal.

As described above, in the example shown in FIG. 5, only the main data line MIOBk is driven, and the main data line MIOTk maintains a precharge level. Therefore, for the pair of local data lines LIOTk and LIOBk, the local data line LIOBk is driven via the data switch circuit IOSW. On the other hand, the local data line LIOTk maintains a precharge level.

A potential change of the local data line LIOTk or LIOBk is reflected to the bit line BLTk or BLBk via the column switch YSW included in the sense amplifier SA. The column switch YSW is controlled by an equalizer selection signal YS generated by a column address or a command signal. The sense amplifier SA includes an equalizer circuit and a cross-coupled circuit described later. An equalize signal EQ that controls the equalizer circuit is also supplied to the sense amplifier SA. The equalize signal EQ is generated by a row address and a command signal.

As described above, in the example shown in FIG. 5, only the local data line LIOBk is driven, and the local data line LIOTk maintains a precharge level. Therefore, for the pair of bit lines BLTk and BLBk, the bit line BLBk is driven via the data switch circuit IOSW and the column switch YSW. On the other hand, the bit line BLTk maintains a precharge level.

As described above, in the semiconductor memory device 10 according to the present embodiment, a bit line (BLTk in the example shown in FIG. 5) connected to the memory cell MC into which data is to be written is not driven, and a bit line (BLBk in the example shown in FIG. 5) that becomes a reference side is driven. Because a bit line to be driven is a reference side, a potential to be written into the reference-side bit line naturally becomes an inversion signal of write data. That is, when data to be overwritten into the memory cell MC is at a high level, the reference-side bit line is driven at a low level. On the other hand, when data to be overwritten into the memory cell MC is at a low level, the reference-side bit line is driven at a high level.

Consequently, a potential difference is generated between a write-side bit line (BLTk in the example shown in FIG. 5) and a reference-side bit line (BLBk in the example shown in FIG. 5). This potential difference is amplified by the sense amplifier SA, and desired data is overwritten into the memory cell MC as a result.

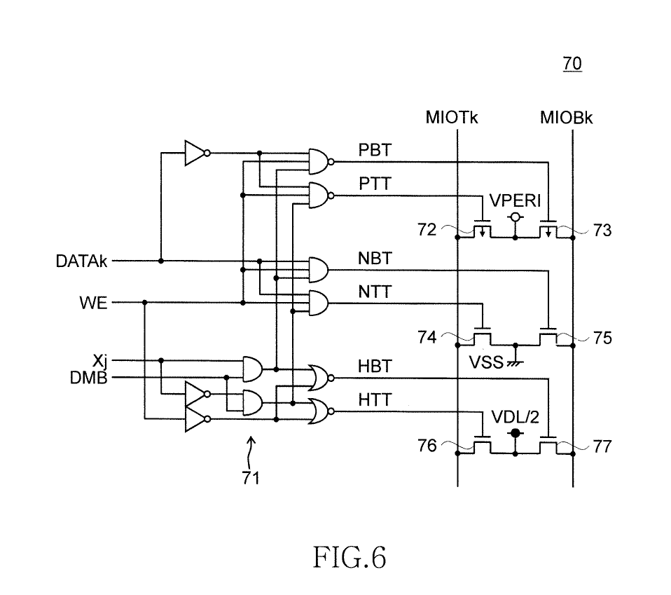

FIG. 6 is a circuit diagram of the write amplifier circuit 70.

As shown in FIG. 6, the write amplifier circuit 70 includes a logic circuit 71 receiving the write data DATAk, the write enable signal WE, the address signal Xj, and the data mask signal DMB, and transistors 72 to 77 controlled by an output signal from the logic circuit 71. Among the transistors 72 to 77, the transistors 72 and 73 are P-channel MOS transistors, and drive the pair of main data lines MIOTk and MIOBk at a high level (VPERI), respectively. The transistors 74 and 75 are N-channel MOS transistor, and drive the pair of main data lines MIOTk and MIOBk at a low level (VSS), respectively. The transistors 76 and 77 are N-channel MOS transistors, and maintain the pair of main data lines MIOBk and MIOBk at a precharge level (VDL/2), respectively.

Signals PTT, PBT, NTT, and NBT output from the logic circuit 71 are supplied to gate electrodes of the transistors 72 to 75, respectively. Only one of the signals PTT, PBT, NTT, and NBT is exclusively activated based on a combination of the write data DATAk and a logic level of the address signal Xj.

Specifically, the signal NBT is activated when both the write data DATAk and the address signal Xj are at a high level. Accordingly, the main data line MIOBk is driven at the low level (VSS). In this case, a signal HTT is also activated. Accordingly, the potential of the main data line MIOBk is maintained at the precharge level (VDL/2).

The signal NTT is activated when the write data DATAk is at a high level and when the address signal Xj is at a low level. Accordingly, the main data line MIOBk is driven at the low level (VSS). In this case, a signal HBT is also activated. Accordingly, the potential of the main data line MIOBk is maintained at the precharge level (VDL/2).

Further, the signal PBT is activated when the write data DATAk is at a low level and when the address signal Xj is at a high level. Accordingly, the main data line MIOBk is driven at the high level (VPERI). In this case, the signal HTT is also activated. Accordingly, the potential of the main data line MIOTk is maintained at the precharge level (VDL/2).

Consequently, the signal PTT is activated when both the write data DATAk and the address signal Xj are at a low level. Accordingly, the main data line MIOTk is driven at the high level (VPERI). In this case, the signal HBT is also activated. Accordingly, the potential of the main data line MIOBk is maintained at the precharge level (VDL/2).

The above operations are performed when the data mask signal DMB is not activated. When the data mask signal DMB is activated, the signals PTT, PBT, NTT, and NBT are all fixed in an inactive state, and both signals are HTT and HBT activated. Accordingly, potentials of the pair of main data lines MIOTk and MIOBk are maintained at the precharge level (VDL/2), respectively regardless of the write data DATAk and a logic level of the address signal Xj.

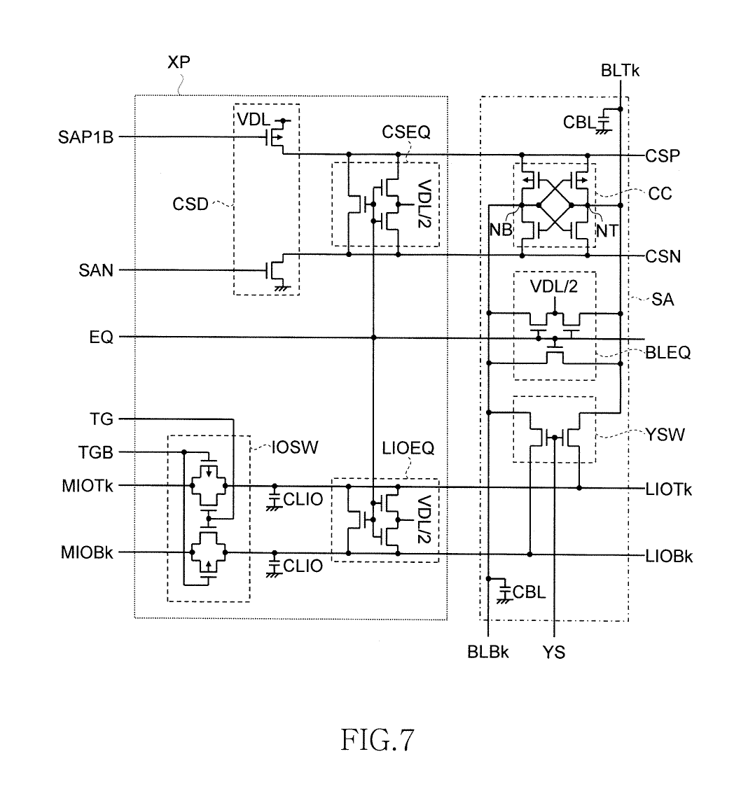

FIG. 7 is a circuit diagram of the cross area XP and the sense amplifier SA.

As shown in FIG. 7, the cross area XP includes: a data switch circuit IOSW that connects the pair of main data lines MIOTk and MIOBk and the pair of local data lines LIOTk and LIOBk, respectively; an equalizer circuit LIOEQ that equalizes the pair of local data lines LIOTk and LIOBk at the precharge potential (=VDL/2); a common source driver CSD that drives common source lines CSP and CSN; and an equalizer circuit CSEQ that equalizes the common source lines CSP and CSN at the precharge potential (=VDL/2).

The data switch circuit IOSW is configured by a so-called transfer gate. That is, a P-channel MOS transistor and an N-channel MOS transistor are connected in parallel between the main data line MIOTk and the local data line LIOTk and between the main data line MIOBk and the local data line LIOBk, respectively. The transfer signal TG is supplied in common to a gate electrode of each N-channel MOS transistor, and an inverted transfer signal TGB is supplied in common to a gate electrode of each P-channel MOS transistor. Accordingly, when the transfer signals TG and TGB are activated, the main data line MIOTk and the local data line LIOTk become substantially at the same potential, and the main data line MIOBk and the local data line LIOBk also become substantially at the same potential.

The equalizer circuit LIOEQ is configured by an N-channel MOS transistor connected between a power source wiring supplied with the precharge potential (VDL/2) and the pair of local data lines LIOTk and LIOBk, and between the pair of local data lines LIOTk and LIOBk. The equalize signal EQ is supplied in common to gate electrodes. Accordingly, when the equalize signal EQ is activated, the pair of local data lines LIOTk and LIOBk are equalized at the precharge potential (VDL/2). The equalizer circuit CSEQ has also the same circuit configuration as that of the equalizer circuit LIOEQ. Therefore, when the equalize signal EQ is activated, the common source lines CSP and CSN are equalized at the precharge potential (VDL/2).

The common source driver CSD is configured by a P-channel MOS transistor connected between a power source wiring supplied with a high-level (VDL) potential and the common source line CSP, and an N-channel MOS transistor connected between a power source wiring supplied with a low-level (VSS) potential and the common source line CSN. Sense activation signals SAP1B and SAN are supplied to gate electrodes of these transistors, respectively. Therefore, when the sense activation signals SAP1B and SAN are activated, the common source line CSP is driven at a VDL level, and the common source line CSN is driven at a VSS level.

As shown in FIG. 7, the common source lines CSP and CSN supply an operation voltage of a cross-coupled circuit CC included in the sense amplifier SA. The cross-coupled circuit CC is a so-called flip-flop circuit. One data node NT is connected to the bit line BLTk, and the other data node NB is connected to the bit line BLBk. Accordingly, when the common source driver CSD is activated, a potential difference between the pair of bit lines BLTk and BLBk is activated by the cross-coupled circuit CC. A bit line of a higher potential is increased to the VDL level, and a bit line of a lower potential is decreased to the VSS level.

The sense amplifier SA includes an equalizer circuit BLEQ. The equalizer circuit BLEQ has the same circuit configuration as those of the equalizer circuits LIOEQ and CSEQ described above. Therefore, when the equalize signal EQ is activated, the pair of bit lines BLTk and BLBk is equalized at the precharge potential (VDL/2).

Further, the sense amplifier SA includes the column switch YSW. The column switch YSW is configured by an N-channel MOS transistor connected between the local data line LIOTk and the bit line BLTk, and an N-channel MOS transistor connected between the local data line LIOBk and the bit line BLBk. The column selection signal YS is supplied to gate electrodes of these transistors. The column selection signal YS is generated based on a column address. When the column selection signal YS is activated, the pair of local data lines LIOTk and LIOBk and the pair of bit lines BLTk and BLBk are connected to each other.

The circuit configuration of the semiconductor memory device 10 according to the present embodiment is as described above. An operation of the semiconductor memory device 10 is explained next.

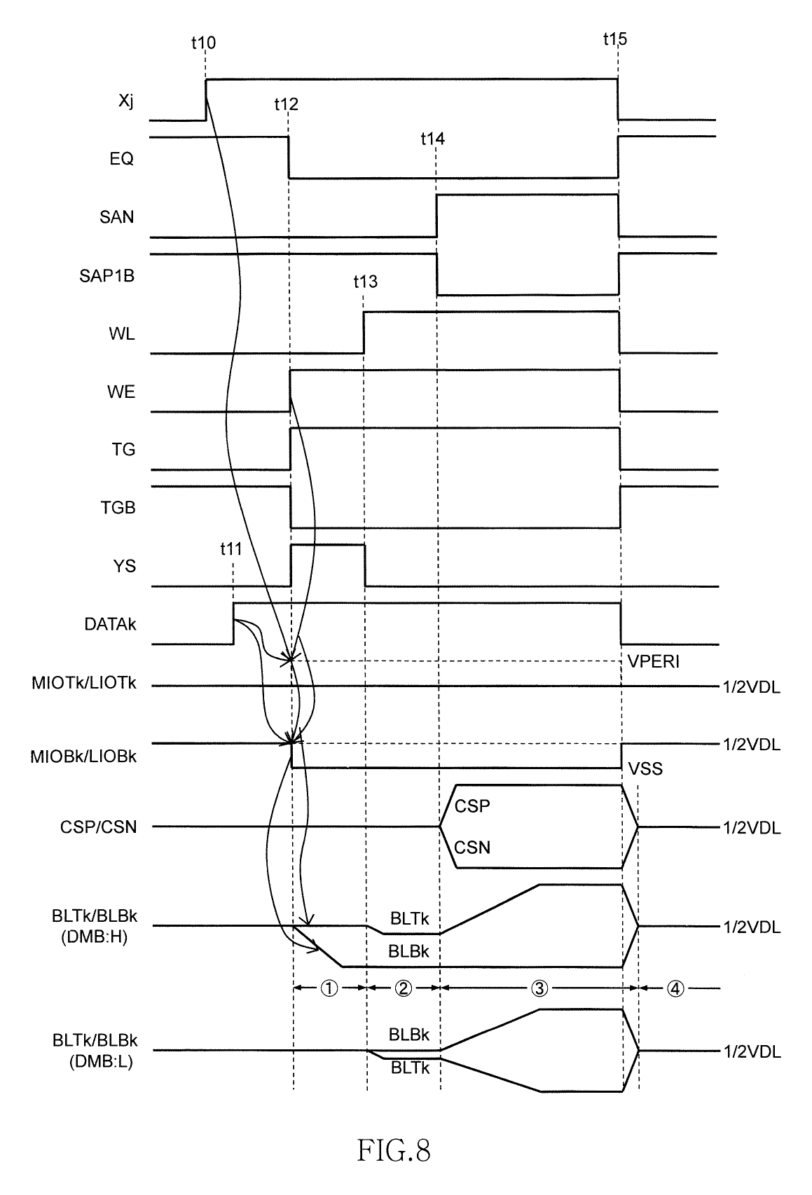

FIG. 8 is a waveform diagram for explaining a write operation of the semiconductor memory device 10 according to the present embodiment.

As shown in FIG. 8, in an initial state (before a time t10), the equalize signal EQ is activated at a high level. Therefore, the pair of main data lines MIOTk and MIOBk, the pair of local data lines LIOTk and LIOBk, and the pair of bit lines BLTk and BLBk are all equalized at the precharge potential (VDL/2).

In this state, a write command and an address signal are input at the time t10. When the write data DATAk is input at a time t11, the equalize signal EQ is inactivated at a low level, and the write enable signal WE, the transfer signals TG and TGB, and the column selection signal YS are activated at a time t12. Accordingly, a potential of one of the pair of main data lines MIOTk and MIOBk changes. As to what direction a potential of what data line changes is as explained above. In FIG. 8, a solid line indicates that both the address signal Xj and the write data DATAk are at a high level, and a broken line indicates that both the address signal Xj and the write data DATAk are at a low level. In the former case, the potential of the main data line MIOBk is decreased to VSS while the potential of the main data line MIOTk is maintained at the precharge potential VDL/2. In the latter case, the potential of the main data line MIOTk is increased to VPERI while the potential of the main data line MIOBk is maintained at the precharge potential VDL/2. VPERI is a high-order side power source potential used in a peripheral circuit. Although not particularly limited, VPERI>VDL. The explanation is continued below based on an example that both the address signal Xj and the write data DATAk are at a high level.

At the time t12, the transfer signals TG and TGB and the column selection signal YS are in an activated state. Therefore, when the potential of the main data line MIOBk is decreased to VSS as described above, the potential of the reference-side bit line BLBk is also decreased toward VSS. On the other hand, the potential of the write-side bit line BLTk does not substantially change.

Next, when the word line WL is activated at a time t13, data of the memory cell MC appears in the write-side bit line BLTk, and the potential of the bit line BLTk slightly changes according to a content of data. In an example shown in FIG. 8, data held in the memory cell MC is at a low level. The potential of the bit line BLTk slightly decreases according to activation of the word line WL. On the other hand, the reference-side bit line BLBk is not connected to any cell capacitor Cs, and does not receive word line noise. Therefore, the potential is not changed.

Next, when the sense activation signals SAP1B and SAN are activated at a time t14, the common source lines CSP and CSN are driven at the VDL level and the VSS level, respectively. Accordingly, the cross-coupled circuit CC is activated, and a potential difference (BLTk>BLBk) generated in the pair of bit lines BLTk and BLBk is amplified. That is, the potential of the bit line BLTk is increased to the VDL level, and the potential of the bit line BLBk is decreased to the VSS level. Consequently, high-level data is overwritten into a selected memory cell MC.

When a precharge command is issued at a time t15, each signal is inactivated, and the word line WL is reset. As a result, a state returns to a precharge state before the time t10, and a series of write operations ends.

As described above, in the semiconductor memory device 10 according to the present embodiment, because only the reference-side bit line is driven without driving the write-side bit line, the potential of other bit line adjacent to the write-side bit line does not fluctuate due to noise between bit lines. Because other bit line adjacent to the write-side bit line is not performed with a write operation but is performed with a read operation and a restore operation, there is a risk that data to be restored is inverted when a potential fluctuates due to noise between bit lines. However, this problem can be solved in the present embodiment.

On the other hand, other bit line adjacent to the reference-side bit line receives an influence of noise between bit lines. However, because the other bit line adjacent to the reference-side bit line belongs to the sense amplifier array SAA not activated in the write operation, data is not damaged by this line. That is, when a bit line “a” shown in FIG. 2 is a write-side bit line, sense amplifier arrays SAA1 and SAA2 adjacent to a corresponding sub-array region are activated, and a sense amplifier array SAA3 is not activated. Noise given to a bit line “d” by driving a reference-side bit line “b” does not damage data. Similarly, when the bit line “b” shown in FIG. 2 is a write-side bit line, the sense amplifier arrays SAA1 and SAA3 adjacent to a corresponding sub-array region are activated, and the sense amplifier array SAA2 is not activated. Therefore, noise given to the bit line “c” by driving the reference-side bit line “a” does not damage data.

When the data mask signal DMB is activated, only a read operation and a restore operation are performed, and data is not overwritten, because potentials of the pair of main data lines MIOTk and MIOBk are fixed at the precharge potential (VDL/2).

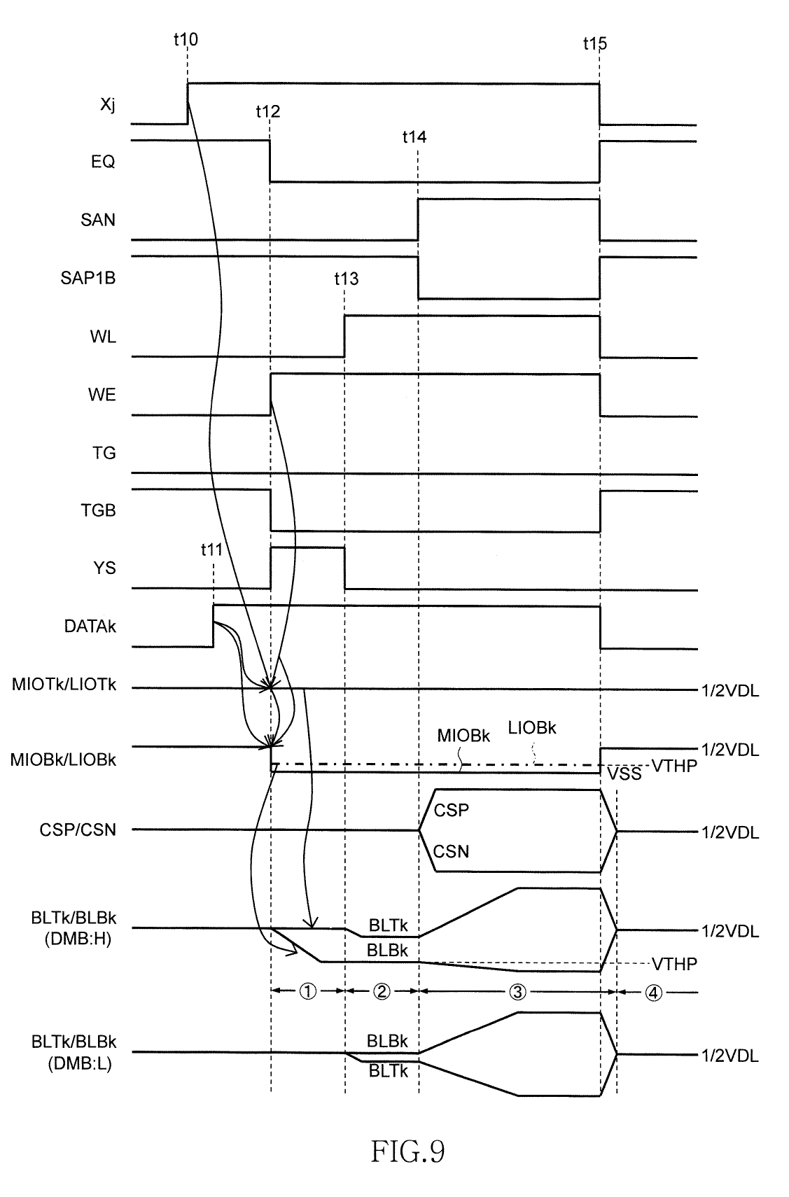

FIG. 9 is another waveform diagram for explaining a write operation of the semiconductor memory device 10 according to the present embodiment.

An example shown in FIG. 9 is different from the operation shown in FIG. 8 in that one of the transfer signals TG and TGB is activated. In this example, only one of the transfer signals TG and TGB is activated depending on whether the write data DATAk is at a high level or a low level. Specifically, when the write data DATAk is at a high level, only the transfer signal TGB is activated, and the transfer signal TG is held in an inactive state, at the time t12 (see FIG. 9). On the other hand, when the write data DATAk is at a low level, only the transfer signal TG is activated, and the transfer signal TGB is held in an inactive state, at the time t12.

As a result, a potential change generated in the local data line LIOBk or LIOBk becomes smaller than a potential change generated in the main data line MIOBk or MIOBk. FIG. 9 shows a case that the write data DATAk is at a high level. In this case, the main data line MIOBk decreases to the VSS level, and the local data line LIOBk decreases to a potential higher than the VSS level by a threshold voltage VTHP of the P-channel MOS transistor. Although not shown, when the write data DATAk is at a low level, the main data line MIOBk increases to the VPERI level, and the local data line LIOBk increases to a potential lower than the VPERI level by a threshold voltage VTHN of the N-channel MOS transistor.

Consequently, as shown in FIG. 9, because the potential of the bit line BLBk becomes VTHP (>VSS), a potential fluctuation of the common source lines CSP and CSN before a sense operation can be suppressed, and an error such as an inversion of data in a memory cell other than that into which data is to be overwritten can be prevented.

In a read operation, read data of a large amplitude can be extracted by activating both of the transfer signals TG and TGB.

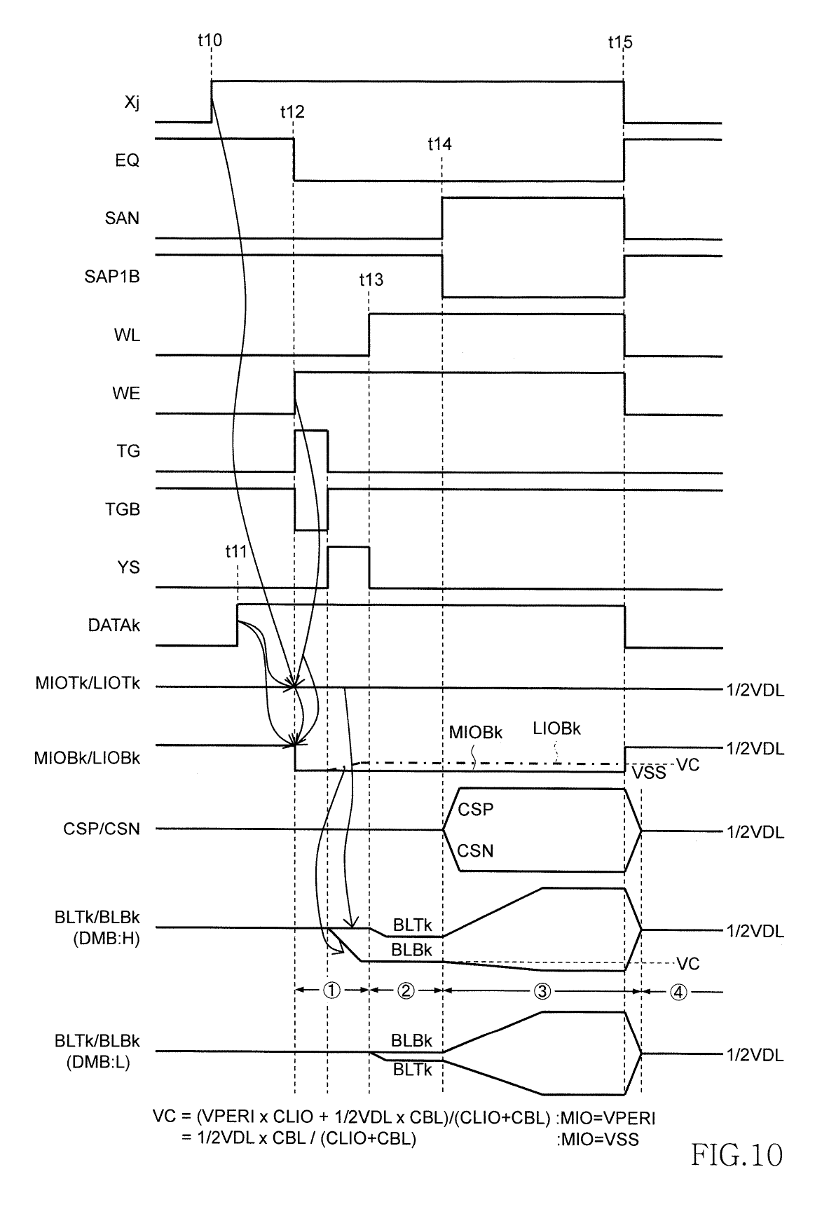

FIG. 10 is still another waveform diagram for explaining a write operation of the semiconductor memory device 10 according to the present embodiment.

An example shown in FIG. 10 is different from the operation shown in FIG. 8 in that the column selection signal YS is activated after the transfer signals TG and TGB are inactivated. In the example shown in FIG. 10, the potential of the local data line LIOBk becomes at the VSS level when the transfer signals TG and TGB are in an activated state. However, because the column selection signal YS is not activated at this time, the potential of the bit line BLBk does not change yet. When the column selection signal YS is activated after the transfer signals TG and TGB are inactivated, a charge share occurs between a parasitic capacitance CLIO of a local data line and a parasitic capacitance CBL of a bit line. As a result, potentials of the local data line LIOBk and the bit line BLBk become at a VC level higher than the VSS level. The value of VC is as shown in FIG. 10, and is determined by a capacitance ratio of the parasitic capacitance CLIO of a local data line and the parasitic capacitance CBL of a bit line.

Consequently, a potential fluctuation of the common source lines CSP and CSN before a sense operation can be suppressed in a similar manner to that shown in FIG. 9. In the example shown in FIG. 9, the potential of the bit line BLTk or BLBk fluctuates when a threshold voltage of a transistor constituting the data switch circuit IOSW fluctuates. However, in the example shown in FIG. 10, a fluctuation of the potential of the bit line BLTk or BLBk in a write operation can be decreased because a charge share based on a parasitic capacitance with a small fluctuation is used.

It is apparent that the present invention is not limited to the above embodiments, but may be modified and changed without departing from the scope and spirit of the invention.

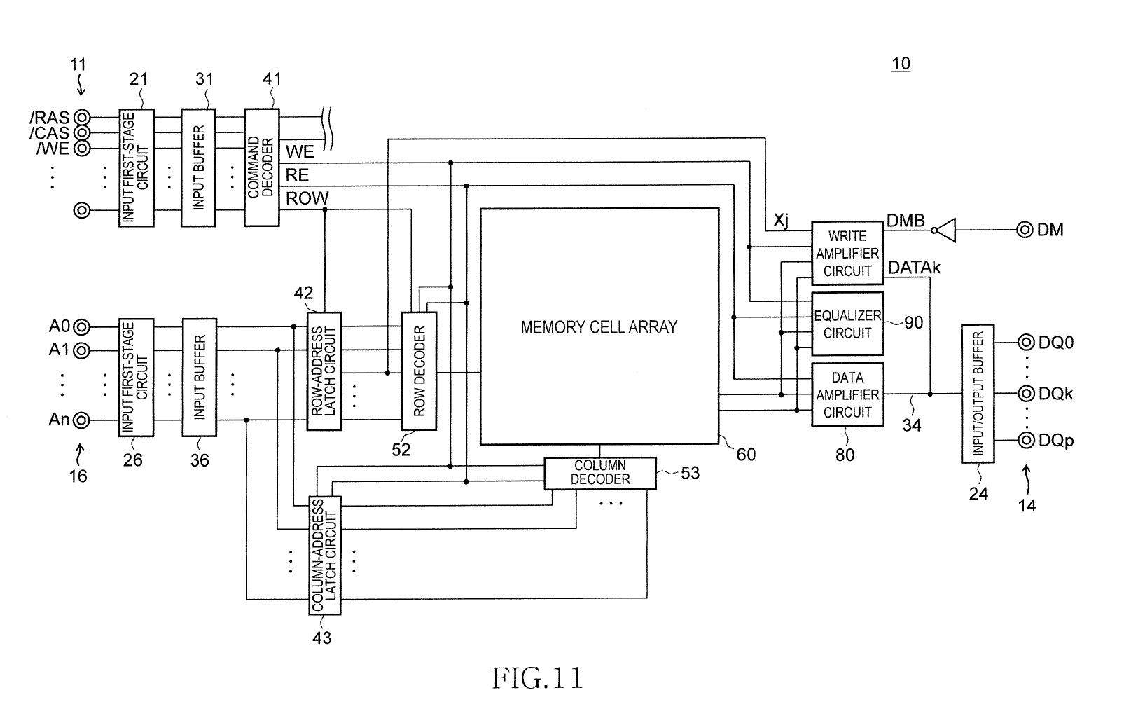

For example, in the above embodiment, there has been explained an application of the present invention to a semiconductor memory device in which a row address and a column address are input at one time. However, the application of the present invention is not limited thereto, and the invention can be also applied to an address-multiplex semiconductor memory device in which a row address and a column address are sequentially input as shown in FIG. 11. According to the semiconductor memory device shown in FIG. 11, a row-address strobe signal /RAS, a column-address strobe signal /CAS, and a write enable signal /WE are supplied to the command input terminal 11. A row address and a column address are input in this order to an address input terminal 16. Input address signals A0 to An are supplied to an input first-stage circuit 26 and an input buffer 36. A row address is supplied to the row-address latch circuit 42, and a column address is supplied to the column-address latch circuit 43. Other points are basically the same as those of the semiconductor memory device 10 shown in FIG. 1.

The operations explained with reference to FIGS. 8 to 10 are only examples of the present invention, and are not necessarily required to be performed in the order described above. For example, an activation of the column selection signal YS, a selection of the word line WL, and an activation of the sense amplifier SA can be performed simultaneously, and these timings can be also adjusted slightly corresponding to various purposes. Timing adjustment can be realized by using a delay circuit.

In the above embodiment, although a potential of a bit line connected to the memory cell MC into which data is to be overwritten is held at a precharge level, a potential of a write-side bit line can be changed as far as the potential change amount is smaller than that of a reference-side bit line.

In the above embodiment, while a pair of data lines is hierarchized by the pair of local data lines LIOT and LIOB and the pair of main data lines MIOT and MIOB, the pair of data lines is not necessarily required to be hierarchized.

In addition, while not specifically claimed in the claim section, the applicant reserves the right to include in the claim section of the application at any appropriate time the following methods:

A control method of a semiconductor memory device having an open-bit-line memory cell array, the method comprising:

equalizing first and second bit lines connected to a same sense amplifier at a precharge level;

driving the second bit line while holding the first bit line at the precharge level in response to a request for a write operation to a memory cell connected to the first bit line; and

driving the first bit line while holding the second bit line at the precharge level in response to a request for a write operation to a memory cell connected to the second bit line.

What is claimed is:

1. A semiconductor device comprising:
a plurality of memory cells each of which includes a cell transistor;
first and second bit lines connected to corresponding memory cells, respectively;
a sense amplifier that is sandwiched between the first and second bit lines, and amplifies a potential difference between the first and second bit lines;
first and second data lines corresponding to the first and second bit lines, respectively; and
a write amplifier that supplies a potential corresponding to write data to the first and second data lines, wherein
the write amplifier changes a potential of the second data line without substantially changing a potential of the first data line at a time of writing the write data into the memory cell by selecting the cell transistor corresponding to the first bit line, and
the write amplifier changes a potential of the first data line without substantially changing a potential of the second data line at a time of writing the write data into the memory cell by selecting the cell transistor corresponding to the second bit line.

2. The semiconductor device as claimed in claim 1, wherein
the write amplifier drives the second data line at a potential lower than a potential of the first data line when the write data to be written into the memory cell connected to the first bit line is at a high level,
the write amplifier drives the second data line at a potential higher than a potential of the first data line when the write data to be written into the memory cell connected to the first bit line is at a low level,
the write amplifier drives the first data line at a potential lower than a potential of the second data line when the write data to be written into the memory cell connected to the second bit line is at a high level, and
the write amplifier drives the first data line at a potential higher than a potential of the second data line when the write data to be written into the memory cell connected to the second bit line is at a low level.

3. The semiconductor device as claimed in claim 1, further comprising:
third and fourth data lines connected to the write amplifier; and
a data switch that connects the first and second data lines to the third and fourth data lines, respectively, wherein
the write amplifier drives one of the first and second data lines by driving one of the third and fourth data lines in a state that the data switch is turned on.

4. The semiconductor device as claimed in claim 3, further comprising a column switch that connects the first and second bit lines to the first and second data lines, respectively, wherein
the write amplifier drives one of the third and fourth data lines in a state that both the data switch and the column switch are turned on.

5. The semiconductor device as claimed in claim 3, wherein
the data switch includes a first conductivity-type transistor and a second conductivity-type transistor respectively connected in parallel between the first data line and the third data line and between the second data line and the fourth data line, and
the write amplifier drives one of the third and fourth data lines in a state that both the first conductivity-type transistor and the second conductivity-type transistor included in the data switch are turned on.

6. The semiconductor device as claimed in claim 4, wherein
the data switch includes a first conductivity-type transistor and a second conductivity-type transistor respectively connected in parallel between the first data line and the third data line and between the second data line and the fourth data line, and
the write amplifier drives one of the third and fourth data lines in a state that one of the first conductivity-type transistor and the second conductivity-type transistor included in the data switch is turned on and the other one is turned off.

7. The semiconductor device as claimed in claim 4, wherein the write amplifier drives one of the first and second data lines by driving one of the third and fourth data lines in a state that the data switch is turned on and the column switch is turned off, and thereafter turns off the data switch and turns on the column switch.

8. The semiconductor device as claimed in claim 1, wherein the write amplifier does not change any potential of the first and second data lines when a data mask signal is activated.

9. A semiconductor device comprising:
first and second sub-array regions;
first and second bit lines provided in the first and second sub-array regions, respectively;
a first sense amplifier region provided between the first and second sub-array regions;
a first sense amplifier that is provided in the first sense amplifier region and amplifies a potential difference between the first and second bit lines; and
a write amplifier that drives the first and second bit lines based on write data, wherein
the write amplifier drives at least the second bit line such that a potential change amount of the second bit line becomes larger than a potential change amount of the first bit line at a time of overwriting the write data into a memory cell connected to the first bit line, and
the write amplifier drives at least the first bit line such that a potential change amount of the first bit line becomes larger than a potential change amount of the second bit line at a time of overwriting the write data into a memory cell connected to the second bit line.

10. The semiconductor device as claimed in claim 9, wherein
the write amplifier drives the second bit line without driving the first bit line at the time of overwriting the write data into a memory cell connected to the first bit line, and
the write amplifier drives the first bit line without driving the second bit line at the time of overwriting the write data into a memory cell connected to the second bit line.

11. The semiconductor device as claimed in claim 9, wherein
the write amplifier supplies an inverted signal of the write data to the second bit line at the time of overwriting the write data into a memory cell connected to the first bit line, and
the write amplifier supplies an inverted signal of the write data to the first bit line at the time of overwriting the write data into a memory cell connected to the second bit line.

12. The semiconductor device as claimed in claim 9, further comprising:
a second sense amplifier region provided at an opposite side of the first sense amplifier region as viewed from the first sub-array region;
a third sense amplifier region provided at an opposite side of the first sense amplifier region as viewed from the second sub-array region;
a third bit line provided adjacent to the first bit line in the first sub-array region; and
a fourth bit line provided adjacent to the second bit line in the second sub-array region, wherein
the third bit line is connected to a second sense amplifier provided in the second sense amplifier region, and
the fourth bit line is connected to a third sense amplifier provided in the third sense amplifier region.

13. The semiconductor device as claimed in claim 12, wherein
the first and second sense amplifiers are activated without activating the third sense amplifier at a time of overwriting the write data into a memory cell connected to the first bit line, and
the first and third sense amplifiers are activated without activating the second sense amplifier at a time of overwriting the write data into a memory cell connected to the second bit line.

14. The semiconductor device as claimed in claim 13, wherein
a memory cell connected to the first bit line and a memory cell connected to the third bit line are selected by a first word line,
a memory cell connected to the second bit line and a memory cell connected to the fourth bit line are selected by a second word line,
data read from a memory cell connected to the third bit line is restored by the second sense amplifier at the time of overwriting the write data into a memory cell connected to the first bit line by activating the first word line, and
data read from a memory cell connected to the fourth bit line is restored by the third sense amplifier at the time of overwriting the write data into a memory cell connected to the second bit line by activating the second word line.

15. A semiconductor device comprising:
a first memory cell array region including a first memory cell, a first bit line, and a first memory cell transistor coupled between the first memory cell and the first bit line;
a second memory cell array region including a second memory cell, a second bit line, and a second memory cell transistor coupled between the second memory cell and the second bit line;
a sense amplifier region intervening between the first and second memory cell array regions, including a sense amplifier coupled to the first and second bit lines to amplify a potential difference between the first and second bit lines;
first and second data lines provided correspondingly to the first and second bit lines, respectively; and
a write amplifier coupled to each of the first and second data lines, driving either one of the first and second data lines from a precharge potential to a write potential determined by a write data and not driving the other of the first and second data lines in a write operation mode.

16. The semiconductor device as claimed in claim 15, wherein the either one of the first and second data lines is the first data line when the second memory cell is selected.

17. The semiconductor device as claimed in claim 16, wherein the write amplifier drives the first data line from the precharge potential to one of the high and low potentials to supply the second memory cell with the other of the high and low potentials.
